(19) United States
(12) Patent Application Publication
(10) Pub. No.: US 2011/0192719 A1
(43) Pub. Date: Aug. 11, 2011

(54) SPUTTERING TARGET FOR FORMING THIN FILM TRANSISTOR WIRING FILM

(75) Inventors: Kazunari Maki, Saitama-shi (JP); Masato Koide, Osaka (JP); Satoru Mori, Okegawa-shi (JP); Kenichi Yaguchi, Ageo-shi (JP); Yosuke Nakasato, Osaka (JP)

(73) Assignees: MITSUBISHI MATERIALS CORPORATION, Tokyo (JP); ULVAC, Inc., Chigasaki-shi (JP)

(21) Appl. No.: 12/998,444

(22) PCT Filed: Oct. 21, 2009
(86) PCT No.: PCT/JP2009/005525

§ 371 Date: Apr. 21, 2011

(30) Foreign Application Priority Data
Oct. 24, 2008 (JP) 2008-273938

(51) Int. Cl. C23C 14/34; C23C 14/06

(52) U.S. Cl. 204/298.13

(57) ABSTRACT

This sputtering target for forming a thin film transistor wiring film has a composition including 0.1 at % to 5 at % of Mg, 0.1 at % to 10 at % of Ca, and the remainder being Cu and inevitable impurities. Either one or both of Mn and Al may further be included at a total amount in a range of 0.1 at % to 10 at %. 0.001 at % to 0.1 at % of P may further be included.

### TECHNICAL FIELD

The present invention relates to a sputtering target for forming a wiring film and a wiring base film (hereinafter, referred to as a wiring film) such as a gate electrode, a source electrode, and a drain electrode of a thin film transistor (hereinafter, referred to as a TFT) with a high adhesion property.

The present application claims priority on Japanese Patent Application No. 2008-273938, filed on Oct. 24, 2008, the content of which is incorporated herein by reference.

### BACKGROUND ART

In general, a flat panel display, such as a liquid crystal display or an organic EL display, has a structure in which a thin film transistor (hereinafter, referred to as a TFT) is formed on a glass substrate, and a copper alloy wiring film is used as a wiring film, such as a gate electrode, a source electrode, and a drain electrode of the TFT.

For example, a liquid crystal display device has been proposed which has a copper alloy wiring film including 1 at % to 5 at % of Mg, and the remainder being Cu and inevitable impurities (see Patent Document 1).

In addition, it is preferable that the copper alloy wiring film be formed of a copper alloy that includes Cu at an amount in a range of about 80 at % or more relative to the entire metal material and metals for forming metal oxides of Mg, Ti, Al, and Cr at an amount in a range of 0.5 to 20 at % relative to the entire metal material (see Patent Document 2).

This copper alloy wiring film is formed as follows. Sputtering is conducted to form a film on a glass substrate and a glass substrate coated with a Si film, and then the film is subjected to a heat treatment. When this heat treatment is performed, additive elements contained in the copper alloy wiring film are moved to the front and rear surfaces of the copper alloy wiring film, and then become oxides. In this way, oxide layers including the additive elements are formed in the front and rear surfaces of the copper alloy wiring film.

This generation of the oxide layer including the additive elements prevents a main component such as Si of the glass substrate and the Si film from diffusing and penetrating into the copper alloy wiring film; and thereby, an increase in the specific resistance of the copper alloy wiring film is prevented. In addition, the generation of the oxide layer including the additive elements improves the adhesion property of the copper alloy wiring film to the glass substrate and the Si film.

A hydrogen treatment (hereinafter, referred to as hydrogen annealing) is performed on the TFT formed on the glass substrate in order to terminate dangling bonds of the Si film of the TFT such that the TFT is reliably operated (see Non-Patent Document 1).

In recent years, the size of the flat panel display has increased, and a large liquid crystal panel with a size of 50 inches or more has been mass-produced. In order to obtain a large flat panel display, the copper alloy wiring film is formed on the surface of a large glass substrate by sputtering. However, there is a variation from area to area (depending on locations) in the specific resistance value of the copper alloy wiring film formed on the surface of the large glass substrate by sputtering. This tendency is noticeable in the copper alloy wiring film formed with a copper alloy target including Mg.

When hydrogen annealing is performed on the TFT which is formed with copper alloy wiring films of a gate electrode, a source electrode, a drain electrode, and the like in order to terminate the dangling bonds of the Si film, the oxide layers formed in the front and rear surfaces of the copper alloy wiring films by the heat treatment are reduced. As a result, the adhesion property due to the oxide layer and the effect of preventing Si from diffusing into the copper alloy wiring film is reduced. In particular, the adhesion property is remarkably reduced.

### PRIOR ART DOCUMENTS

### Patent Documents

Patent Document 1: Japanese Unexamined Patent Application, First Publication H09-43628
Patent Document 2: Japanese Unexamined Patent Application, First Publication 2005-166757

### Non-Patent Document

Non-Patent Document 1: 2003 FPD Technology Outlook, pp. 155 to 165

### DISCLOSURE OF THE INVENTION

### Problems to be Solved by the Invention

The present invention aims to provide a sputtering target capable of forming a copper alloy wiring film having a uniform specific resistance value with a small variation in the specific resistance value, and a high adhesion property.

### Means for Solving the Problems

The inventors have conducted a study so as to obtain a copper alloy wiring film having the following characteristics.

(i) The copper alloy wiring film has a uniform specific resistance value with a small variation in the specific resistance value.

(ii) Even when hydrogen annealing is performed, the oxide layers formed in the front and rear surfaces of the copper alloy wiring film are less likely to be reduced; and as a result, the reduction in the adhesion property obtained by the oxide layer is small.

As a result, the inventors found that it was important to perform sputtering with a copper alloy target having a composition including 0.1 at % to 5 at % of Mg, 0.1 at % to 10 at % of Ca, and the remainder being Cu and inevitable impurities, if necessary, further including either one or both of Mn and Al at a total amount in a range of 0.1 at % to 10 at %, and 0.001 at % to 0.1 at % of P.

As a result of the study, a copper alloy thin film formed by sputtering using the copper alloy target having the above-mentioned composition had a uniform specific resistance value with a smaller variation in the specific resistance value, as compared to a copper alloy thin film that was formed by sputtering using a conventional copper alloy target having a composition including 1 at % to 5 at % of Mg, and the remainder being Cu and inevitable impurities.

In addition, in the copper alloy film formed by using the copper alloy target having the above-mentioned composition, the chemical stability of the oxide layer was higher, that is, the oxide layer formed by the heat treatment was less likely to be reduced, as compared to the conventional copper alloy film. Therefore, since a reduction in adhesion property after the hydrogen annealing was small, the copper alloy film had good characteristics as a wiring film of a TFT.

The present invention has been made on the basis of the results of the above-mentioned study and has the following requirements.

A sputtering target for forming a thin film transistor wiring film (a wiring film of a thin film transistor) of the present invention has a composition including 0.1 at % to 5 at % of Mg, 0.1 at % to 10 at % of Ca, and the remainder being Cu and inevitable impurities.

In the sputtering target for forming a thin film transistor wiring film (a wiring film of a thin film transistor) of the present invention, either one or both of Mn and Al may further be included at a total amount in a range of 0.1 at % to 10 at %.

0.001 at % to 0.1 at % of P may further be included.

The sputtering target of the present invention may be used to form a wiring film having a laminated structure as well as a wiring film having a single-layer structure. In the case where the sputtering target is used to form the wiring film having a laminated structure, it may be used to form a wiring base film, which is the lowermost layer.

### EFFECTS OF THE INVENTION

When sputtering is performed using the target of the present invention, it is possible to form a copper alloy thin film having a small variation in specific resistance value, a high adhesion property to the surface of a glass substrate and the surface of a Si film, and a small specific resistance value, even when the glass substrate has a large size. Therefore, it is possible to form a copper alloy wiring film of a large and high-definition thin film transistor.

In addition, in a wiring film of a TFT and a wiring base film of a TFT formed by using the target of the present invention, the oxide layer formed by a heat treatment is less likely to be reduced. Therefore, a reduction in adhesion property after hydrogen annealing is small; and as a result, the film has good characteristics as a wiring film of a TFT and the adhesion property of the film to the surface of the glass substrate and the surface of the Si film is further improved. Therefore, it is possible to form a wiring film of a TFT for a large and high-definition flat panel display.

### BEST MODE FOR CARRYING OUT THE INVENTION

The reason why the range of the component composition of the sputtering target according to the present invention is limited as described above will be explained.

Mg:

Mg exerts an effect to refine crystal grains; and thereby, the occurrence of thermal defects such as hillocks and voids is prevented in a copper alloy thin film which configures a wiring film of a thin film transistor, and migration resistance is improved.

During a heat treatment, oxide layers including Mg are formed in the front and rear surfaces of the copper alloy thin film. In this way, a main component such as Si of a glass substrate and a Si film is prevented from diffusing and penetrating into the copper alloy wiring film. As a result, an increase in the specific resistance of the copper alloy wiring film is prevented. In addition, the adhesion property of the copper alloy wiring film to the glass substrate and the Si film is improved.

Mg is added in order to obtain the above-mentioned effects. However, in the case where the content of Mg is less than 0.1 at %, a desired effect is not obtained; and therefore, the content range is not preferable. In the case where the content of Mg is more than 5 at %, further improvements in characteristics are not obtained, and the specific resistance value of the copper alloy wiring film increases. As a result, the sufficient function of the wiring film is not obtained; and therefore, the content range is not preferable. Therefore, the content of Mg contained in the copper alloy thin film is set to be in a range of 0.1 at % to 5 at %.

Ca:

In the case where sputtering is performed using a target including 0.1 at % to 5 at % of Mg and 0.1 at % to 10 at % of Ca, a variation in the specific resistance value of the formed copper alloy thin film from area to area is reduced. Therefore, Ca is included.

In the case where sputtering is performed using a target including less than 0.1 at % of Mg and less than 0.1 at % of Ca, a desired effect is not obtained. In the case where sputtering is performed using a target including more than 5 at % of Mg and more than 10 at % of Ca, further improvements in desired characteristics are not obtained, and the resistance of the copper alloy thin film increases; and therefore, the content range is not preferable.

With regard to the copper alloy thin film formed by sputtering using a target including these components, during a heat treatment process, a multiple oxide or an oxide solid solution including Ca and at least one of Mg, Cu, and Si is formed in the front and rear surfaces of the copper alloy thin film. In this way, in particular, the adhesion property of the copper alloy thin film to the glass substrate and the Si film after a hydrogen treatment process is further improved. Since the oxide formed in the front and rear surfaces of the copper alloy thin film includes the multiple oxide or the oxide solid solution including Ca and at least one of Mg, Cu, and Si which has a high chemical stability, the chemical stability of the copper alloy wiring is improved.

Mn and Al:

In the case where these components are included together with Mg and Ca, these components exert an effect to further improve the adhesion property and the chemical stability. The reason is as follows.

With regard to a film formed by sputtering with a target including these components, during a heat treatment process, a multiple oxide or an oxide solid solution including Ca, at least one of Mg, Cu, and Si, and either one or both of Mn and Al is formed in the front and rear surfaces of the copper alloy thin film. In this way, in particular, the adhesion property of the copper alloy thin film to the glass substrate and the Si film after a hydrogen treatment process is further improved. Since the oxide formed in the front and rear surfaces of the copper alloy thin film includes the multiple oxide or the oxide solid solution including Ca, at least one of Mg, Cu, and Si which has a high chemical stability, and either one or both of Mn and Al, the chemical stability of the copper alloy wiring is improved.

However, in the case where the total amount of either one or both of Mn and Al is less than 0.1 at %, the effect of improving the desired functions (adhesion property and chemical stability) is not obtained; and therefore, the content range is not preferable. In the case where the total amount is more than 10 at %, characteristics are not improved, and the specific resistance value of the copper alloy wiring film increases; and therefore, the content range is not preferable.

Therefore, in the case where either one or both of Mn and Al are included, the total amount thereof is set to be in a range of 0.1 at % to 10 at %.

P:

By including a small amount of P, a copper alloy can be casted easily without deteriorating the characteristics of the copper alloy thin film, such as a specific resistance, an occurrence of hillocks and voids, and an adhesion property. Therefore, P is added, if needed.

However, in the case where P is added at an amount of less than 0.001 at %, a desired effect is not obtained. In the case where P is added at an amount of more than 0.1 at %, the casting performance is not improved. Therefore, in the case where P is included, the content thereof is set to be in a range of 0.001 at % to 0.1 at %.

Next, an example of a method for manufacturing a target for forming a wiring film of a thin film transistor of the present invention will be described.

First, oxygen-free copper with a degree of purity of 99.99% or more is melted by a high frequency induction heating in a high-purity graphite crucible in an inert gas atmosphere. Then, 0.1 at % to 5 at % of Mg and 0.1 at % to 10 at % of Ca are added to the obtained molten metal. If needed, either one or both of Mn and Al are added at a total amount in a range of 0.1 at % to 10 at %. In addition, if needed, 0.001 at % to 0.1 at % of P is added and melted.

The obtained molten metal is casted in an inert gas atmosphere and is then rapidly solidified. Then, if needed, hot rolling is performed. Finally, stress relief annealing is performed to obtain a rolled body. Then, the surface of the rolled body is processed by using a lathe machine. In this way, a target is manufactured.

Here, the target may be manufactured by the following method. Mg, Ca, Mn, Al, and P are directly added to a molten metal of oxygen-free copper, then master alloy powder is manufactured by, for example, atomization. Thereafter, the master alloy powder is hot-pressed.

### EXAMPLES

Oxygen-free copper with a degree of purity of 99.99 mass % was prepared, and the oxygen-free copper was melted by a high frequency induction heating in a high-purity graphite crucible in an Ar gas atmosphere. Mg and Ca were added to the obtained molten metal. If needed, at least one of Mn and Al was added to the molten metal. In addition, if needed, P was further added. These components were melted. The addition amounts thereof were adjusted such that the molten metals had component compositions shown in Tables 1 to 3.

The obtained molten metals were casted in a cooled carbon mold, and the metal castings (ingots) were subjected to hot rolling. Then, finally, stress relief annealing was performed to obtain rolled bodies.

Next, the surfaces of the rolled bodies were processed by using a lathe machine to manufacture copper alloy sputtering targets (hereinafter, referred to as inventive targets) 1 to 30 according to examples of the invention, copper alloy sputtering targets (hereinafter, referred to as comparative targets) 1 to 6 according to comparative examples, sputtering targets (hereinafter, referred to as targets according to the related art) 1 and 2 according to examples of the related art that had a disk shape, an outside diameter of 200 mm, a thickness of 10 mm, and the component compositions shown in Tables 1 to 3.

With regard to a brittle ingot that could not be subjected to hot rolling, a sputtering target was directly cut out from the ingot without being subjected to hot rolling.

Backing plates made of oxygen-free copper were prepared, and each of the inventive targets 1 to 30, the comparative targets 1 to 6, and the targets 1 and 2 according to the related art was placed on the oxygen-free copper backing plate, and then was soldered thereto with an indium solder at a temperature of 200° C. In this way, each of the targets 1 to 30 according to the examples of the invention, the targets 1 to 6 according to the comparative examples, and the targets 1 and 2 according to the examples of the related art was jointed to the oxygen-free copper backing plate to produce a target with a backing plate.

The target with a backing plate was disposed such that a distance between the target and a glass substrate (a glass substrate 1737 produced by Corning Company having sizes of diameter: 200 mm and thickness: 0.7 mm) coated with an amorphous Si film became 70 mm.

Wiring thin films that had a radius of 100 mm and a thickness of 300 nm and consisted of a copper alloy including a very small amount of oxygen were formed in the surfaces of the glass substrates coated with the amorphous Si films by using the targets having the component compositions shown in Tables 1 to 3 under the following conditions:

Power source: direct current;

Sputtering power: 600 W;

Attained degree of vacuum: 4×10⁻⁵ Pa;

Atmosphere gas composition: a mixed gas of 99 vol % of Ar and 1 vol % of oxygen;

Gas pressure: 0.2 Pa; and

Glass substrate heating temperature: 150° C.

All the formed wiring thin films had a circular shape.

Each of the obtained circular wiring thin films was charged in a heating furnace, and was subjected to a heat treatment in an Ar atmosphere under conditions where the temperature rising rate was 5° C./min, the maximum temperature was 350° C., and the holding time was 30 minutes.

Then, with regard to each of the circular wiring thin films which were subjected to the heat treatment, specific resistances were measured by a four-probe method at the center, at a point distant from the center by 50 mm, and at a point distant from the center by 100 mm, and the difference between the maximum value and the minimum value of the specific resistances was calculated. The results are shown in Tables 1 to 3, and the variations in the specific resistance value of the wiring thin films were evaluated.

In addition, with regard to each of the circular wiring thin films which were subjected to the heat treatment, a cross-cut adhesion test was performed as follows.

Equally spaced cut lines were made at 1 mm intervals in a grid arrangement in each of the wiring thin films in accordance with JIS-K5400. Then, a scotch tape manufactured by 3M Company was put on the surface of the wiring thin film and was peeled off. Thereafter, an area ratio (area %) of the wiring thin film remained to adhere to the glass substrate within a 10-mm-square in a center portion of the glass substrate was measured. The measurement results are shown in Tables 1 to 3, and the adhesion properties of the wiring thin films to the glass substrate coated with the amorphous Si film were evaluated.

With regard to each of the wiring thin films which were subjected to the heat treatment, five portions in the surface thereof were observed by a SEM at a magnification of 5,000, and it was observed whether or not hillocks and voids were generated. The results are shown in Tables 1 to 3.

In addition, the wiring copper alloy films 1 to 30 according to the examples of the invention, the wiring copper alloy films 1 to 6 according to the comparative examples, and the wiring copper alloy films 1 and 2 according to the examples of the related art which had been subjected to the heat treatment were subjected to a hydrogen annealing under the following conditions:

Atmosphere: a mixed gas (1 atmosphere) of H₂/N₂=50/50 (vol %);

Temperature: 300° C.; and

Holding time: 30 minutes.

With regard to each of the wiring copper alloy films 1 to 30 according to the examples of the invention, the wiring copper alloy films 1 to 4 according to the comparative examples, and the wiring copper alloy films 1 and 2 according to the examples of the related art which were subjected to the hydrogen annealing, a cross-cut adhesion test was performed by the same method as described above. The results are shown in Tables 1 to 3. With regard to the wiring copper alloy films 1 to 30 according to the examples of the invention, the wiring copper alloy films 1 to 6 according to the comparative examples, and the wiring copper alloy films 1 and 2 according to examples of the related art which were subjected to the hydrogen annealing, the adhesion properties to the glass substrate coated with the amorphous Si film were evaluated.

TABLE 1

| | | | | | | | | | | | | | Cross-cut adhesion test | |
|---|---|---|---|---|---|---|---|---|---|---|---|---|---|---|
| | | | | | | | | Measured specific resistance value | | | | | Ratio of wiring thin film | |
| | | Component composition | | | | | | of wiring thin film (μΩcm) | | | | | adhered to glass | |
| | | of target (at %) | | | | | | | | | Difference | | substrate (area %) | |
| | | | | | | | Cu and | | 50 mm | 100 mm | between | Presence | Before | After |
| | | | | | | | inevitable | | from | from | maximum and | of hillocks | hydrogen | hydrogen |
| Target | | Mg | Ca | Mn | Al | P | impurities | Center | center | center | minimum | and voids | annealing | annealing |
| Examples of | 1 | 0.1 | 9.8 | — | — | — | Balance | 3.1 | 3.1 | 3.0 | 0.1 | none | 100 | 95 |
| the invention | 2 | 0.5 | 0.2 | — | — | — | Balance | 1.9 | 1.9 | 1.9 | 0.0 | none | 100 | 96 |
| | 3 | 1.0 | 0.1 | — | — | — | Balance | 2.1 | 2.1 | 2.1 | 0.0 | none | 100 | 91 |
| | 4 | 1.5 | 2.8 | — | — | — | Balance | 2.5 | 2.5 | 2.5 | 0.0 | none | 100 | 100 |
| | 5 | 1.8 | 3.6 | — | — | — | Balance | 2.7 | 2.7 | 2.7 | 0.0 | none | 100 | 100 |
| | 6 | 2.3 | 0.5 | — | — | — | Balance | 2.4 | 2.3 | 2.4 | 0.1 | none | 100 | 100 |
| | 7 | 2.9 | 6.2 | — | — | — | Balance | 3.3 | 3.3 | 3.3 | 0.0 | none | 100 | 100 |
| | 8 | 3.9 | 0.1 | — | — | — | Balance | 2.9 | 2.8 | 2.8 | 0.1 | none | 100 | 92 |
| | 9 | 4.9 | 2.0 | — | — | — | Balance | 3.1 | 3.2 | 3.2 | 0.1 | none | 100 | 100 |
| | 10 | 0.1 | 0.8 | 0.2 | — | — | Balance | 2.2 | 2.1 | 2.2 | 0.1 | none | 100 | 96 |
| | 11 | 0.5 | 0.2 | 0.5 | — | — | Balance | 2.6 | 2.6 | 2.6 | 0.0 | none | 100 | 100 |
| | 12 | 1.0 | 0.3 | 5.3 | — | — | Balance | 8.3 | 8.3 | 8.1 | 0.2 | none | 100 | 100 |
| | 13 | 1.5 | 6.0 | 2.1 | — | — | Balance | 5.3 | 5.3 | 5.2 | 0.1 | none | 100 | 100 |
| | 14 | 2.1 | 0.3 | 1.0 | — | — | Balance | 3.6 | 3.6 | 3.6 | 0.0 | none | 100 | 100 |
| | 15 | 2.7 | 0.1 | 0.5 | — | — | Balance | 3.0 | 3.0 | 3.1 | 0.1 | none | 100 | 100 |

TABLE 2

| | | | | | | | | | | | | | Cross-cut adhesion test | |
|---|---|---|---|---|---|---|---|---|---|---|---|---|---|---|
| | | | | | | | | Measured specific resistance value | | | | | Ratio of wiring thin film | |
| | | Component composition | | | | | | of wiring thin film (μΩcm) | | | | | adhered to glass | |
| | | of target (at %) | | | | | | | | | Difference | | substrate (area %) | |
| | | | | | | | Cu and | | 50 mm | 100 mm | between | Presence | Before | After |
| | | | | | | | inevitable | | from | from | maximum and | of hillocks | hydrogen | hydrogen |
| Target | | Mg | Ca | Mn | Al | P | impurities | Center | center | center | minimum | and voids | annealing | annealing |
| Examples of | 16 | 3.0 | 6.4 | 2.1 | — | — | Balance | 5.6 | 5.8 | 5.6 | 0.2 | none | 100 | 100 |
| the invention | 17 | 0.1 | 0.8 | — | 0.2 | — | Balance | 2.0 | 2.0 | 2.0 | 0.0 | none | 100 | 98 |
| | 18 | 0.5 | 1.4 | — | 0.5 | — | Balance | 2.4 | 2.4 | 2.4 | 0.0 | none | 100 | 100 |
| | 19 | 1.0 | 2.0 | — | 2.2 | — | Balance | 3.3 | 3.2 | 3.1 | 0.2 | none | 100 | 100 |
| | 20 | 1.4 | 6.3 | — | 1.8 | — | Balance | 3.7 | 3.6 | 3.6 | 0.1 | none | 100 | 100 |
| | 21 | 2.1 | 0.9 | — | 2.0 | — | Balance | 3.2 | 3.3 | 3.3 | 0.1 | none | 100 | 100 |
| | 22 | 2.5 | 1.5 | — | 4.0 | — | Balance | 4.3 | 4.2 | 4.2 | 0.1 | none | 100 | 100 |
| | 23 | 2.8 | 6.4 | — | 2.0 | — | Balance | 4.3 | 4.3 | 4.3 | 0.0 | none | 100 | 100 |
| | 24 | 0.9 | 0.1 | 1.3 | 1.6 | — | Balance | 4.1 | 4.2 | 4.2 | 0.1 | none | 100 | 100 |
| | 25 | 1.9 | 2.9 | 1.9 | 2.2 | — | Balance | 5.9 | 5.9 | 6.0 | 0.1 | none | 100 | 100 |
| | 26 | 4.0 | 0.8 | 2.0 | 5.7 | — | Balance | 7.5 | 7.4 | 7.4 | 0.1 | none | 100 | 100 |
| | 27 | 5.0 | 0.5 | 0.5 | 1.6 | — | Balance | 4.6 | 4.5 | 4.6 | 0.1 | none | 100 | 100 |
| | 28 | 0.5 | 0.1 | 0.2 | 0.9 | 0.001 | Balance | 2.6 | 2.7 | 2.6 | 0.1 | none | 100 | 100 |
| | 29 | 5.0 | 0.2 | 0.5 | 1.4 | 0.05 | Balance | 4.3 | 4.1 | 4.2 | 0.2 | none | 100 | 100 |
| | 30 | 3.6 | 1.1 | 2.1 | 5.7 | 0.1 | Balance | 7.9 | 8.0 | 7.8 | 0.2 | none | 100 | 100 |

TABLE 3

| | | | | | | | | | | | | | Cross-cut adhesion test | |
|---|---|---|---|---|---|---|---|---|---|---|---|---|---|---|
| | | | | | | | | Measured specific resistance value | | | | | Ratio of wiring thin | |
| | Component composition | | | | | | | of wiring thin film (μΩcm) | | | | | film adhered to glass | |
| | of target (at %) | | | | | | | | | | Difference | | substrate (area %) | |
| | | | | | | | Cu and | | 50 mm | 100 mm | between | Presence | Before | After |
| | | | | | | | inevitable | | from | from | maximum and | of hillocks | hydrogen | hydrogen |
| Target | | Mg | Ca | Mn | Al | P | impurities | Center | center | center | minimum | and voids | annealing | annealing |
| Comparative | 1 | 0.03* | 0.02* | — | — | — | Balance | 1.9 | 1.9 | 1.9 | 0.0 | Present | 25 | 11 |
| examples | 2 | 8.5* | 8.3 | — | — | — | Balance | 5.8 | 5.9 | 5.9 | 0.1 | none | 100 | 100 |
| | 3 | 3.2 | 0.02* | — | — | — | Balance | 2.6 | 2.9 | 3.6 | 1.0 | none | 79 | 41 |
| | 4 | 6.8* | 13.7* | — | — | — | Balance | 5.6 | 5.6 | 5.8 | 0.2 | none | 100 | 100 |
| | 5 | 3.5 | 0.01* | 0.01* | 0.01* | — | Balance | 2.7 | 3.1 | 3.6 | 0.9 | none | 83 | 48 |
| | 6 | 3.3 | 7.2 | 3.8* | 8.5* | — | Balance | 10.7 | 10.8 | 10.9 | 0.2 | none | 100 | 100 |
| Examples | 1 | 3.1 | —* | — | — | — | Balance | 2.3 | 2.8 | 3.3 | 1.0 | none | 50 | 28 |
| of related | 2 | 4.8 | —* | — | — | — | Balance | 2.9 | 3.1 | 4.0 | 1.1 | none | 62 | 35 |
| art | | | | | | | | | | | | | | |

*indicates a value out of the range of the present invention.

The following can be understood from the results shown in Tables 1 to 3.

(i) With regard to the wiring thin films (the wiring copper alloy films 1 and 2 according to the examples of the related art) formed by sputtering using the targets 1 and 2 according to the examples of the related art that solely contained Mg with Cu, differences in the specific resistance between the center portion and the peripheral portion are large. In addition, the adhesion properties to the glass substrate coated with the amorphous Si film are low.

In contrast, with regard to the wiring thin films (the wiring copper alloy films 1 to 30 according to the examples of the invention) formed by sputtering using the targets 1 to 30 according to the examples of the invention that included Mg and Ca and included Mn, Al, and P if needed, differences in the specific resistance between the center portion and the peripheral portion are small; and therefore, the variations in the specific resistance value are small. In addition, the adhesion properties to the glass substrate coated with the amorphous Si film are high in both cases of before and after the hydrogen annealing.

(ii) With regard to the wiring thin film (the wiring copper alloy film 1 according to the comparative example) formed by sputtering using the target 1 according to the comparative example that included Mg and Ca at amounts lower than the ranges of the present invention, hillocks and voids are generated. The adhesion properties are low before and after the hydrogen annealing. Therefore, the wiring copper alloy film 1 according to the comparative example is not preferable as a wiring thin film.

With regard to the wiring thin films (the wiring copper alloy films 2 and 4 according to the comparative examples) formed by sputtering using the target 2 according to the comparative example that included Mg at an amount more than the range of the present invention and the target 4 according to the comparative example that included Mg and Ca at amounts more than the ranges of the present invention, the specific resistance values are larger than those of the wiring thin films (the wiring copper alloy films 1 to 9 according to the examples of the invention) according to the examples of the invention formed by using the targets 1 to 9 according to the examples of the invention that included Mg and Ca. Therefore, the wiring copper alloy films 2 and 4 according to the comparative examples are not preferable as wiring thin films.

(iii) With regard to the wiring thin films (the wiring copper alloy films 3 and 5 according to the comparative examples) formed by sputtering using the targets 3 and 5 according to the comparative examples that included Ca, Mn, and Al at amounts less than the ranges of the present invention, the adhesion properties are low before and after the hydrogen annealing, and the variations in the specific resistance value are large. Therefore, the wiring copper alloy films 3 and 5 according to the comparative examples are not preferable.

With regard to the wiring thin film (the wiring copper alloy film 6 according to the comparative example) formed by sputtering using the target 6 according to the comparative example that included Mn and Al at a total amount more than the range of the present invention, the specific resistance value is excessively large. Therefore, the wiring copper alloy film 6 according to the comparative example is not preferable as a wiring thin film.

### INDUSTRIAL APPLICABILITY

By using the target according to the present invention, it is possible to manufacture a copper alloy thin film that has a small variation in specific resistance value, a high adhesion property to the surfaces of a glass substrate and a Si film, and a small specific resistance value. Therefore, the target can be suitably applied to a process of manufacturing a copper alloy wiring film of a thin film transistor in a large and high-definition flat panel display.

1. A sputtering target for forming a thin film transistor wiring film, having a composition comprising 0.1 at % to 5 at % of Mg, 0.1 at % to 10 at % of Ca, and the remainder being Cu and inevitable impurities.

2. The sputtering target for forming a thin film transistor wiring film according to claim 1, wherein the sputtering target further comprises either one or both of Mn and Al at a total amount in a range of 0.1 at % to 10 at %.

3. The sputtering target for forming a thin film transistor wiring film according to claim 2, wherein the sputtering target further comprises 0.001 at % to 0.1 at % of P.
